(19) United States
(12) Patent Application Publication
(10) Pub. No.: US 2008/0079439 A1
(43) Pub. Date: Apr. 3, 2008

(54) Development environment and basic tenets for enabling robust embedded diagnostics in RF systems

(76) Inventors: David W. Murray, Windsor, CA (US); Kim Chung Thi Thanh, Rohnert Park, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/515,061

(22) Filed: Sep. 1, 2006

(51) Int. Cl. G01R 31/08

(52) U.S. Cl. 324/527

(57) ABSTRACT

For a communication system that employs interconnected communication components and defines a communication pathway running through the communication components and through interconnections therebetween, the communication pathway having test points, an apparatus for performing diagnostic tests on the communication system comprises testing agents residing on-board the communication components, and a test controller, coupled for communication over the communication pathway. The test controller includes a test signal apparatus coupled to send a test signal over the communication pathway, detectors, coupled to the test points, for sensing communication activity at the test points responsive to the test signal, and a communication activity analyzer, coupled to receive communication activity information from the detectors, for analyzing the received communication activity information to identify a fault and isolate a communication component containing the fault.

### BACKGROUND OF THE INVENTION

The present invention relates to diagnostic testing for electronic equipment.

Conventional diagnostic testing arrangements have involved coupling a test system, such as a production line Unix workstation, to an instrument or piece of equipment to be tested. Troubleshooting software applications, in the form of BASIC or C language programs or shell scripts, etc., reside within the test system.

When such troubleshooting software applications are executed, the test system, and the instrument to be tested, communicate through a communication interface. For instance, many such troubleshooting applications use an IEEE 488 General Purpose Interface Bus (GPIB) connection between the UNIX workstation and the instrument.

It would be advantageous to employ standard network communications for such diagnostic testing, obviating the need for a diagnostic-specific interface such as the GPIB and allowing for remote testing. It would also be advantageous to execute diagnostic testing on-board the equipment to be tested.

### SUMMARY OF THE INVENTION

For a communication system that employs interconnected communication components and defines a communication pathway running through the communication components and through interconnections therebetween, the communication pathway having test points, an apparatus for performing diagnostic tests on the communication system comprises testing agents residing on-board the communication components, and a test controller, coupled for communication over the communication pathway. The test controller includes a test signal apparatus coupled to send a test signal over the communication pathway, detectors, coupled to the test points, for sensing communication activity at the test points responsive to the test signal, and a communication activity analyzer, coupled to receive communication activity information from the detectors, for analyzing the received communication activity information to identify a fault and isolate a communication component containing the fault.

Further features and advantages of the present invention, as well as the structure and operation of preferred embodiments of the present invention, are described in detail below with reference to the accompanying exemplary drawings.

### BRIEF DESCRIPTION OF THE DRAWINGS

FIG. 1 is a block diagram of a system embodying the invention.

FIG. 2 is a more detailed block diagram of an embodiment the system of FIG. 1.

FIG. 3 is a flowchart showing operation of the system of FIG. 1.

### DETAILED DESCRIPTION

A system embodying the invention includes self-contained embedded diagnostics for a piece of electronic equipment. Among other fields, such a system may be employed in a measurement apparatus for radiofrequency (hereinafter “RF”) systems.

In such systems, it is desirable to be able to self-diagnose problems which can be solved by replacing sub-assemblies, cables, etc., without requiring the use of external test and measurement equipment. When such a problem is diagnosed, service personnel not necessarily requiring great expertise or training, can replace the problem component.

In the discussion which follows, the term “indicted” will be used to describe a component, sub-assembly, etc., for which a problem has been diagnosed. Also, the terms “component” and “communication component” will be used interchangeably, to refer broadly and without limitation to any sub-assembly, cable, interface, component, etc., within a piece of equipment, for which a fault may occur. The term “fault” will refer to any problem that is, or can be, isolated within a particular component of the piece of equipment.

A diagnostic performed by a system embodying the invention can identify an indicted component, a failing component, or the component most likely to fail or to have failed. Also, the particular nature of the fault or failure can be identified.

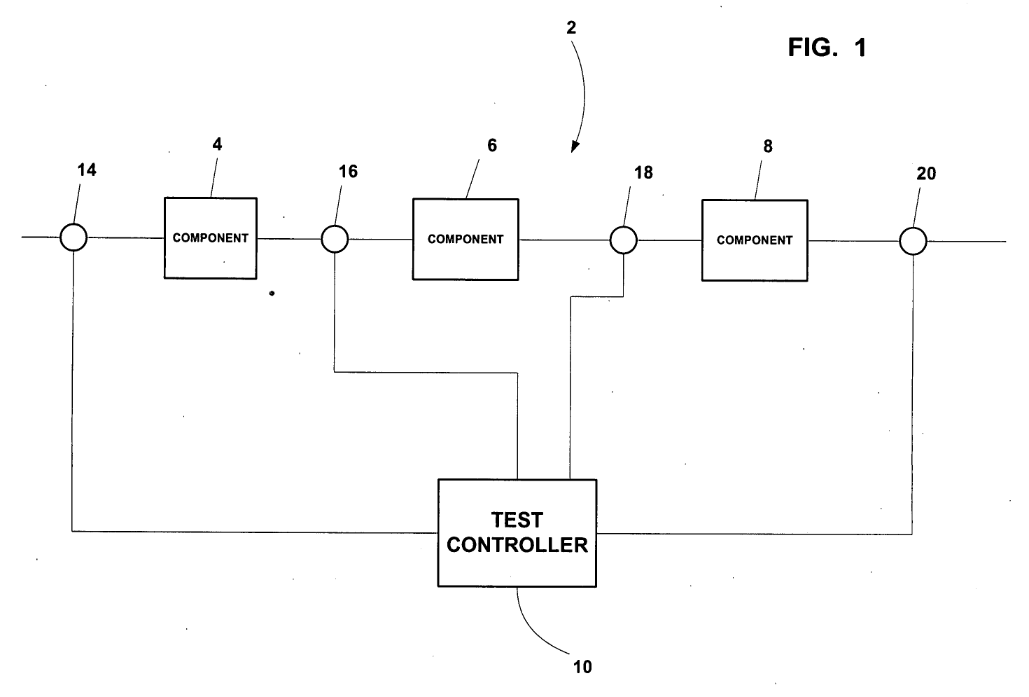

FIG. 1 is a schematic block-level diagram of an apparatus according to an embodiment of the invention. The apparatus may be included within a piece of communication equipment, test equipment, etc., or within multiple distinct modules of any of the foregoing, or a communication system.

FIG. 1 shows a communication pathway 2, which runs horizontally from left to right, and passes through components 4, 6, and 8. As noted above, the components 4, 6, and 8 may include any sub-assembly, cable, interface, component, etc. A test controller 10 is coupled to the communication pathway at various test points 14, 16, 18, and 20. In one embodiment of the invention, the test controller 10 is embedded within the piece of equipment 2 itself. The equipment 2 may, for instance, employ a standard user interface such as a Windows-based interface. The operator may execute a diagnostic by using the user interface to log in (as appropriate), and enter commands to execute a diagnostic which may include one or more tests, a sequence of tests, etc. See, for instance, co-pending U.S. patent application Ser. No. ______, “DIAGNOSTIC APPLICATIONS FOR ELECTRONIC EQUIPMENT PROVIDING EMBEDDED AND REMOTE OPERATION AND REPORTING”, filed Sep. 1, 2006.

In operation, a test signal is injected into the communication pathway. The test signal may be generated by the test controller 10 or by an outside signal source (not shown). The signal may be injected at a test point such as one of the test points 14, 16, 18, and 20, or at an input point or starting point (not shown) of the communication pathway 2.

For a given input test signal, it is possible to predict what signal should be present at a given one of the test points. It is also possible to determine, for a test point signal different from that which should be present, whether a nearby component is failing, and what the nature of the fault is.

Therefore, the test controller 10 can monitor the signals at the test points 14, 16, 18, and 20, and use those signals to identify faulty components. For instance, if signals at the test points 14 and 16 are normal, but a signal at the test point 18 is abnormal, this might indicate a fault in the component 6. Also, if the signal at the test point 18 is, for instance, stuck in an idle state instead of showing signal traffic, it might indicate that a circuit element in the component 6 such as a transistor amplifier might have failed, or a cable connector might have a broken wire.

In such a system, a problem diagnosis can be completely self-contained, and require no external measurement equipment. Where a failed hardware component is identified, an operator or technician can replace a failed component (a cable, sub-assembly, etc.), with a high confidence level that the replacement will successfully repair the equipment. Since the most likely failing sub-component is identified on the indicted parent sub-assembly then the task of fault finding to component level is significantly reduced.

Once a faulty component is identified, it may also be desirable to perform a more detailed diagnosis to identify and fix a particular failing sub-component, sub-assembly, etc., within the component. Such more detailed diagnosis can be performed either while the component is still within the equipment, or performed separately after it has been extracted and replaced. Such additional more detailed diagnosis may need more specific models, testing, test equipment, etc.

Test results can be accumulated for purposes such as statistical analysis. In one embodiment, failure information, information on indicted sub-assemblies, etc., is stored in a failure history record store, such as an electrically alterable programmable read-only memory (EEPROM) apparatus.

The embedded diagnostic can be executed remotely, responsive to a remote command received over a communication network coupled to the equipment.

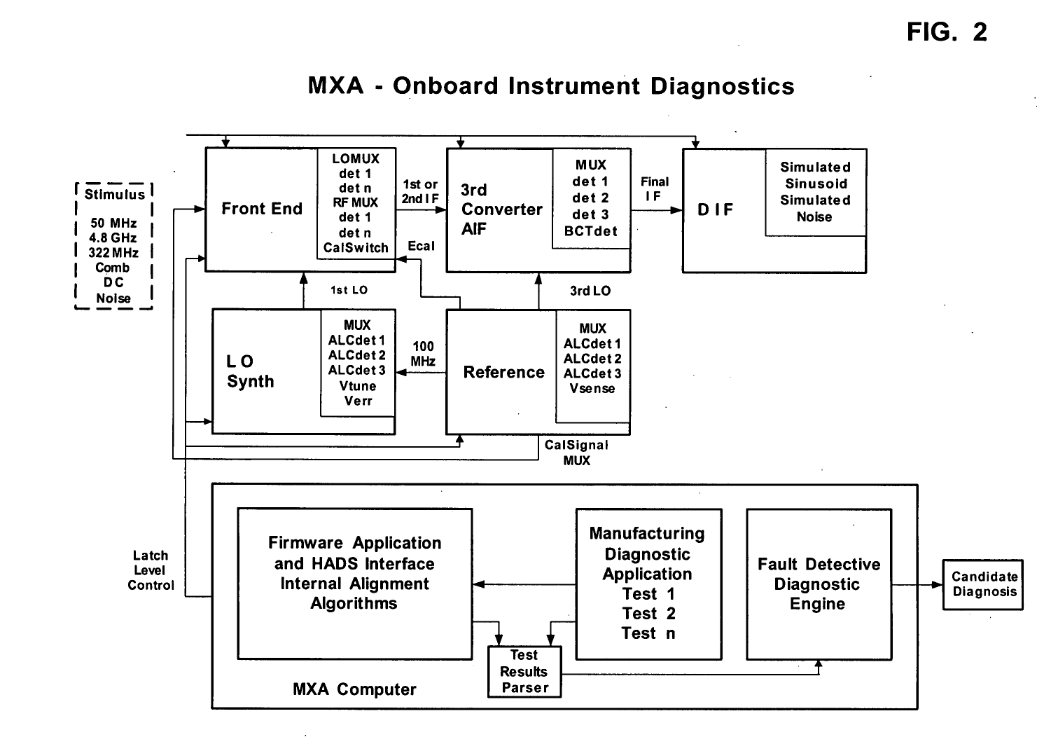

FIG. 2 is a more detailed example of a piece of electronic communications equipment having an embedded diagnostic apparatus embodying the invention. Specifically, FIG. 2 shows a high level block diagram of a spectrum analyzer. Many of the labeled elements will be familiar to those skilled in the radiofrequency (RF) spectrum analyzer arts, so the comments which follow will pertain mainly to a method for testing the illustrated instrument, as per an embodiment of the invention.

The LO (Local Oscillator) provides the signal that is used in the down conversion of the RF signal to an IF (intermediate frequency) signal in much the same way a SuperHetrodyne radio receiver works. To avoid mixer image frequencies and to get from GHz frequencies down to a baseband frequency range (MHz) that can be digitally processed, the illustrated analyzer uses 2 or 3 conversion stages. The final IF is the intermediate frequency stage that can be processed by an embedded diagnostic measurement system embodying the present invention.

Normally, employing embedded diagnostics onto RF measurement systems would present a few issues.
1. The measurement paths are few, and usually include the majority of components in the instrument, from the RF input to the final IF measurement. By contrast, for instance, digital circuitry tends to follow a more parallel hardware topology.
2. Most of the measurements in the instrument are made at the final IF stage.

These two issues present a problem for embedded RF diagnostics. If one of these long RF paths has a component which is so faulty that no signal reaches the Final IF, then there is no way to know where the signal went bad.

Typically the test engineer would half split a problem like this. They would try to find a signal half way along the measurement path. If the signal was good, then they know that the bad component lies in the latter half of the measurement path. If the signal is bad, then they know the failing component (assuming there is only one) is in the first half of the RF path. Once the test engineer has established within which half of the signal path the signal has been impaired, he/she will now half split the problem again across that half, and repeat this technique until the fault has been narrowed down and localized, and is isolated.

Detectors, as shown schematically in FIG. 1, are placed all along the measurement path of the instrument of FIG. 2. Then, the half-splitting technique just described is practiced in the instrument of FIG. 2.

Parallel topology also helps mitigate RF issues in these long measurement paths. In the instrument of FIG. 2, the measurement assemblies have a good number of parallel paths that can be used to bifurcate many RF path faults. In RF Analyzers the RF path is “supported” by the LO Synth and the Reference Assembly, in the sense that both are required to produce the valid IF frequencies found along the RF measurement path. These supporting circuits have their own means of detecting signals, and so can be to a great extent independently verified as working.

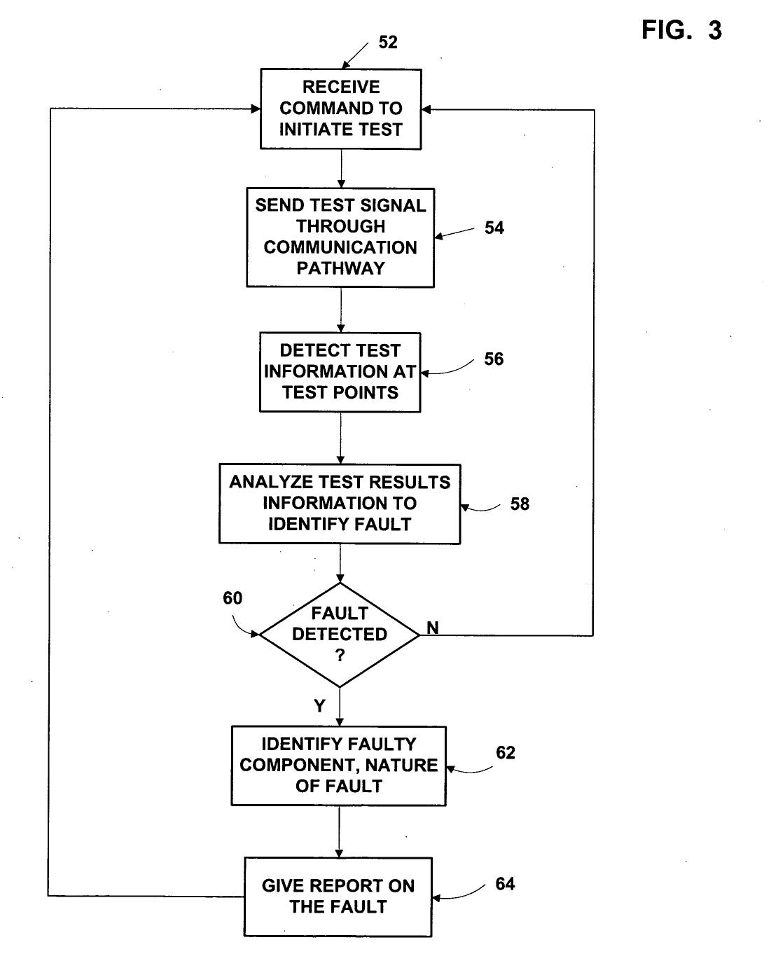

FIG. 3 is a flowchart showing operation of a diagnostic test apparatus such as that of FIGS. 1 and 2. Initially, a test command is received (52). Such a command can come from a user input interface on the equipment itself, via a remote command received over a network or other communication line coupled to the equipment, or from an automatic test scheduling and control apparatus.

Responsive to the test command, the test controller sends (54) a test signal through the communication pathway. The test controller then monitors the various test points along the communication pathway, to detect and obtain test information (56) regarding how the various components of the equipment, along the communication pathway, are behaving. The detected test information is analyzed (58) to determine whether the components are functioning normally, or whether an abnormality that may be indicative of a fault or problem has been detected.

Based on that analysis, it is determined (60) first, whether a fault has been detected, and second, based on which test points show which abnormalities, which component seems to be faulty. If no fault is detected, the test apparatus idles or performs other functions until another test command (52) is received.

If a fault is detected, the faulty component, and the nature of the fault, are analyzed (62) and reported to the system operator (64), through a user interface, printer, display, etc. The report is in a form that will direct the operator to replace the component believed to be faulty. Where an operator does not necessarily have great expertise with the equipment but has facility with swapping components in and out, the report is sufficient to enable the operator to take action that will enable the equipment to keep on functioning.

The form and content of the report can be analogized to an incident in Arthur C. Clarke's science fiction novel 2001: A Space Odyssey. The HAL 9000 computer on board the spacecraft Discovery directed astronaut David Bowman to replace the AE-35 unit, which was reported to be faulty and, if it were to fail, would have disabled the communication link to Earth. Astronaut Bowman then performed an extravehicular activity to replace the AE-35 unit.

Although the present invention has been described in detail with reference to particular embodiments, persons possessing ordinary skill in the art to which this invention pertains will appreciate that various modifications and enhancements may be made without departing from the spirit and scope of the claims that follow.

What is claimed is:

1. An apparatus for performing diagnostic tests on a piece of equipment, the piece of equipment employing interconnected components and defining a communication pathway running through the components and through interconnections therebetween, the communication pathway having test points, the apparatus comprising:
testing agents residing on-board the components; and
a test controller, coupled for communication over the communication pathway, and including (i) a test signal apparatus coupled to send a test signal over the communication pathway, (ii) detectors, coupled to the test points, for sensing communication activity at the test points responsive to the test signal, and (iii) a communication activity analyzer, coupled to receive communication activity information from the detectors, for analyzing the received communication activity information to identify a fault and isolate a component containing the fault.

2. An apparatus as recited in claim 1 further comprising a control interface for receiving commands to direct the test controller to test the piece of equipment.

3. An apparatus as recited in claim 2, wherein the control interface includes a user interface for:
(i) allowing a user to control testing operation of the apparatus, and
(ii) providing the user with results of the testing operation, the results of the testing operation including the identified fault and the isolated component containing the fault.

4. An apparatus as recited in claim 2, wherein the control interface includes an interface for receiving commands generated by an external testing system.

5. An apparatus as recited in claim 4, wherein the control interface includes a software implementation in a software development environment that is commercially available to users.

6. An apparatus as recited in claim 1, further comprising a detector for detecting the presence of a new component within the piece of equipment, and wherein the test signal apparatus includes a new component test stimulus generator for generating a test signal suitable for testing the new component.

7. An apparatus as recited in claim 1, wherein the testing agents include apparatus for testing control parameters.

8. An apparatus as recited in claim 7, wherein:
(a) the piece of equipment includes a radiofrequency (RF) communication system; and
(ii) the apparatus for testing control parameters includes apparatus for testing at least one of (i) phase locked loop status, (ii) loop integrator voltages, ALC drive voltages, (iv) amplifier gain settings, (v) mixer bias levels, and (vi) internal alignment calibrations such as path gain.

9. A method for performing a diagnostic test on a piece of equipment, the piece of equipment employing interconnected components and defining a communication pathway running through the components and through interconnections therebetween, the communication pathway having test points, the method comprising:
sending a test signal over the communication pathway;
sensing communication activity at the test points responsive to the test signal,
analyzing the received communication activity information to identify a portion of the communication pathway containing a fault; and
repeating the sending, sensing, and analyzing, for successively smaller portions of the communication pathway, thereby isolating a communication component containing the fault.
